(19) United States
(12) Patent Application Publication
(10) Pub. No.: US 2007/0006912 A1
(43) Pub. Date: Jan. 11, 2007

(54) HIGH-EFFICIENCY POWER FACTOR IMPROVEMENT CIRCUIT

(75) Inventors: Bong Hwan KWON, Pohang-city, Kyungsangbuk-do (KR); Jung Min KWON, Pohang-city, Kyungsangbuk-do (KR)

Correspondence Address: ROTHWELL, FIGG, ERNST & MANBECK, P.C., 1425 K STREET, N.W., SUITE 800, WASHINGTON, DC, 20005, US

(73) Assignees: POSTECH FOUNDATION, Pohang-city (KR); POSTECH ACADEMY-INDUSTRY FOUNDATION, Pohang-city (KR)

(21) Appl. No.: 11/425,852

(22) Filed: Jun. 22, 2006

(30) Foreign Application Priority Data
Jul. 9, 2005 (KR) 10-2005-0061953

(51) Int. Cl. H01L 31/00

(52) U.S. Cl. 136/256

(57) ABSTRACT

Provided is a high-efficiency power factor improvement circuit which is capable of simultaneously handling a rectification operation performed by rectifying bridge diodes and a power factor improvement operation and reducing switching loss using a snubber circuit when an input voltage is boosted to a predetermined level. The power factor improvement circuit includes: a boost converter circuit which comprises rectifying bridge diodes that constitute a bridge circuit; and a snubber circuit which reduces switching loss caused due to the reverse recovery current characteristics of the rectifying bridge diodes.

### CROSS-REFERENCE TO RELATED PATENT APPLICATION

This application claims the benefit of Korean Patent Application No. 10-2005-0061953, filed on 9 Jul. 2005, in the Korean Intellectual Property Office, the disclosure of which is incorporated herein in its entirety by reference.

### BACKGROUND OF THE INVENTION

1. Field of the Invention

The present invention relates to a high-efficiency power factor improvement circuit, and more particularly, a high-efficiency power factor improvement circuit which can simultaneously handle an operation performed by rectifying bridge diodes and a power factor improvement operation and can reduce switching loss using a snubber circuit when an input voltage is boosted to a predetermined level.

2. Description of the Related Art

In general, power supplies comprise a power factor improvement circuit for attenuating harmonic components and an output voltage control circuit for controlling an output voltage. In detail, a power factor improvement circuit improves a power factor and generates an output voltage with a uniform level, and an output voltage control circuit receives the output voltage generated by the power factor improvement circuit, generates an output voltage with a desired level using the received output voltage, and outputs the output voltage with the desired level. In other words, a power factor improvement circuit makes an output voltage uniform while improving a power factor. A conventional power factor improvement circuit generally comprises rectifying bridge diodes generating a direct current (DC) by rectifying an input alternating current (AC) and a boost converter boosting an input voltage to a predetermined level.

A conventional power factor improvement circuit, however, has a low power efficiency because of power loss caused by semiconductor devices of the conventional power factor improvement circuit. This problem can be solved by simultaneously performing a rectification operation and a power factor improvement operation.

FIG. 1 is a circuit diagram of a conventional power factor improvement circuit which is capable of reducing power loss caused by semiconductor devices by simultaneously performing a rectification operation and a power factor improvement operation. Referring to FIG. 1, the conventional power factor improvement circuit includes a boost converter circuit 100 which includes a rectifying bridge circuit comprising a plurality of rectifying diodes D₁, D₂, D_{S1}, and D_{S2}, an inductor Lᵢ, switches S₁ and S₂, and an output condenser C₀. The conventional power factor improvement circuit can reduce power loss caused by semiconductor devices by using the boost converter circuit 100. However, the conventional power factor improvement circuit may cause switching loss due to the reverse recovery characteristics of the rectifying diodes D₁, D₂, D_{S1}, and D_{S2} in the process of switching the rectifying diodes D₁, D₂, D_{S1}, and D_{S2} by turning on or off the switches S₁ and S₂.

### SUMMARY OF THE INVENTION

The present invention provides a high-efficiency power factor improvement circuit which can simultaneously perform an operation performed by rectifying bridge diodes and a power factor improvement operation and can reduce switching loss using a snubber circuit when an input voltage is boosted to a predetermined level.

According to an aspect of the present invention, there is provided a power factor improvement circuit. The power factor improvement circuit includes: a boost converter circuit which comprises rectifying bridge diodes that constitute a bridge circuit; and a snubber circuit which reduces switching loss caused due to the reverse recovery current characteristics of the rectifying bridge diodes.

The snubber circuit may include: first and second inductors which are connected to a middle portion of the bridge circuit; first and second diodes which are connected to the first and second inductors, respectively; and a snubber inductor which is connected to the cathode terminals of the first and second diodes.

The snubber circuit may include: first and second inductors which are connected to a middle portion of the bridge circuit; first and second snubber inductors which are connected to the first and second inductors, respectively; and first and second diodes which are connected to the first and second snubber inductors, respectively. The cathode terminals of the first and second diodes may be connected to each other.

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit diagram of a conventional power factor improvement circuit;

FIG. 2 is a circuit diagram of a power factor improvement circuit according to an exemplary embodiment of the present invention; and

FIG. 3 is a circuit diagram of a power factor improvement circuit according to another exemplary embodiment of the present invention.

### DETAILED DESCRIPTION OF THE INVENTION

The present invention will now be described more fully with reference to the accompanying drawings in which exemplary embodiments of the invention are shown. Terms used in this disclosure have been defined in consideration of their functions in this disclosure and may have different meanings depending on a user's intent or understanding. Therefore, the terms are defined based on the invention claimed in this disclosure.

In the drawings, like reference numerals represent like elements, and thus their detailed descriptions will not be repeated.

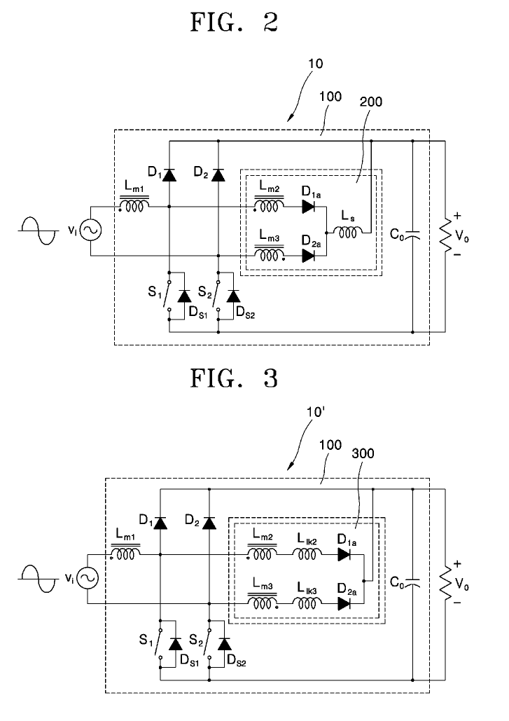

FIG. 2 is a circuit diagram of a power factor improvement circuit 10 according to an exemplary embodiment of the present invention, and FIG. 3 is a circuit diagram of a power factor improvement circuit 10′ according to another exemplary embodiment of the present invention.

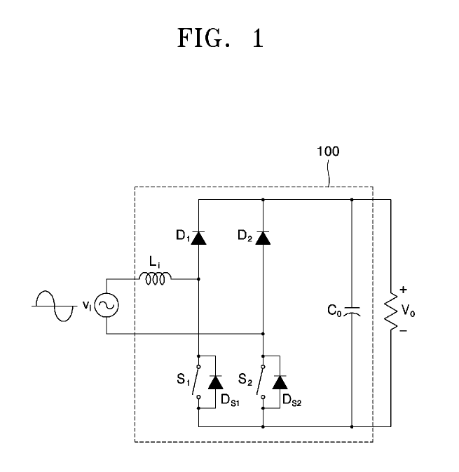

Referring to FIG. 2, the power factor improvement circuit 10 includes a boost converter circuit 100 which comprises: rectifying bridge diodes D₁, D₂, D_{S1}, and D_{S2} and a snubber circuit 200. The boost converter circuit 100 is almost the same as the boost converter circuit 100 of FIG. 1. In other words, the boost converter circuit 100 of FIG. 2 includes: an inductor Lₘ₁ which is connected on one side of an alternating input voltage vᵢ; the rectifying bridge diodes D₁, D₂, D_{S1}, and D_{S2} which constitute a bridge circuit; 2 switches S₁ and S₂ which are connected in parallel to the respective pairs of rectifying bridge diodes; and a boost output condenser C₀ which smoothes a voltage output from the bridge circuit and outputs the smoothed voltage.

The snubber circuit 200 includes: first and second inductors Lₘ₂ and Lₘ₃ which are connected to a middle portion of the bridge circuit; first and second diodes D₁ and D₂ₐ, which are connected to the first and second inductors Lₘ₂ and Lₘ₃, respectively; and a snubber inductor Lₛ which is connected to a cathode terminal of each of the first and second diodes D₁ₐ and D₂ₐ.

Referring to FIG. 3, the power factor improvement circuit 10′ is almost the same as the power factor improvement circuit 10 of FIG. 2.

In other words, the power factor improvement circuit 10′ includes a boost converter circuit 100 which comprises: an inductor Lₘ₁; rectifying bridge diodes D₁, D₂, D_{S1}, and D_{S2}; and a snubber circuit 300. The snubber circuit 300 includes: first and second inductors Lₘ₂ and Lₘ₃ which are connected to a middle portion of a bridge circuit constituted by the rectifying bridge diodes D₁, D₂, D_{S1}, and D_{S2}; first and second snubber inductors Lₗₖ₂ and Lₗₖ₃ which are connected to the first and second inductors Lₘ₂ and Lₘ₃, respectively; and first and second diodes D₁ₐ and D₂ₐ which are connected to the first and second snubber inductors Lₗₖ₂ and Lₗₖ₃, respectively. Cathode terminals of the first and second diodes D₁ₐ and D₂ₐ are connected to each other and to both terminals of an output voltage V₀.

The operations of the power factor improvement circuits 10 and 10′ according to embodiments of the present invention will now be described with reference to FIGS. 2 and 3.

Referring to FIGS. 2 and 3, the output voltage V₀ is obtained by controlling the alternating input voltage Vᵢ. In the boost converter circuit 100, a rectification operation performed by the rectifying bridge diodes D₁, D₂, D_{S1}, and D_{S2} is carried out together with a power factor improvement operation. The snubber circuit 200 or 300 reduces switching loss when the alternating input voltage Vᵢ is boosted to a predetermined level.

In detail, referring to FIG. 2, the power factor improvement circuit 10 includes the snubber circuit 200 for reducing switching loss and the boost converter circuit 100 for rectifying the alternating input voltage Vᵢ and boosting the rectification result to the level of the output voltage V₀.

Referring to FIG. 3, the power factor improvement circuit 10′ includes the snubber circuit 300 for reducing switching loss and the boost converter 100 for rectifying the alternating input voltage Vᵢ and boosting the rectification result to the level of the output voltage V₀.

The inductor Lₘ₁ of the boost converter circuit 100 is a primary coupled inductor, and the inductors Lₘ₂ and Lₘ₃ are secondary coupled inductors. The inductors Lₘ₁, Lₘ₂, and Lₘ₃ are single coupled inductors. The diodes D₁ and D₂ are output diodes of the boost converter circuit 100.

The number of turns of the secondary coupled inductors Lₘ₂ and Lₘ₃ of the power factor improvement circuit 10 of FIG. 2 is smaller than the number of turns of the primary coupled inductor Lₘ₁. When the switches S₁ and S₂ of the boost converter circuit 100 are turned off, an output current of the boost converter circuit 100 is transmitted to the snubber diodes D₁ₐ and D₂ₐ, thereby eliminating the reverse recovery current characteristics of the output diodes D₁ and D₂. When the switches S₁ and S₂ are turned on, the snubber inductor Lₛ limits a reverse recovery current that flows into the diodes D₁ₐ and D₂ₐ.

In the power factor improvement circuit 10′ of FIG. 3, the inductors Lₗₖ₂ and Lₗₖ₃ of the snubber circuit 300 may be realized as snubber leakage inductors according to the degree to which they are connected to the inductor Lₗₖ₁ of the boost converter circuit 100, which is a primary coil. The inductors Lₗₖ₂ and Lₗₖ₃ can enhance efficiency by reducing switching loss caused by the reverse recovery current characteristics of the diodes D₁ and D₂ when the switches S₁ and S₂ are turned on. The inductors Lₗₖ₂ and Lₗₖ₃ of the snubber circuit 300 may also be realized as inductors other than the snubber leakage inductors.

According to the present invention, it is possible to reduce switching loss caused by the reverse recovery current characteristics of diodes by using a snubber circuit and to simultaneously handle a rectification operation performed by rectifying bridge diodes and a power factor improvement operation.

As described above, the power factor improvement circuit according to the present invention can simultaneously handle a rectification operation performed by rectifying bridge diodes and a power factor improvement operation and can reduce switching loss using a snubber circuit when an input voltage is boosted to a predetermined level.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A power factor improvement circuit comprising:
a boost converter circuit which comprises rectifying bridge diodes that constitute a bridge circuit; and
a snubber circuit which reduces switching loss caused due to the reverse recovery current characteristics of the rectifying bridge diodes.

2. The power factor improvement circuit of claim 1, wherein the boost converter circuit comprises:
an inverter which is connected on one side of an alternating input voltage;
4 rectifying diodes which constitute a bridge circuit;
2 switches which are connected in parallel to the respective pairs of rectifying diodes; and
a condenser which smoothes a voltage output from the bridge circuit and outputs the smoothed voltage.

3. The power factor improvement circuit of claim 1, wherein the snubber circuit comprises:
first and second inductors which are connected to a middle portion of the bridge circuit;
first and second diodes which are connected to the first and second inductors, respectively; and
a snubber inductor which is connected to the cathode terminals of the first and second diodes.

4. The power factor improvement circuit of claim 1, wherein the snubber circuit comprises:
first and second inductors which are connected to a middle portion of the bridge circuit;
first and second snubber inductors which are connected to the first and second inductors, respectively; and
first and second diodes which are connected to the first and second snubber inductors, respectively,
wherein the cathode terminals of the first and second diodes are connected to each other.
